(19) United States
(12) Patent Application Publication
(10) Pub. No.: US 2008/0295421 A1
(43) Pub. Date: Dec. 4, 2008

(54) System and method for installing a semiconductor manufacturing apparatus

(76) Inventors: Jan Dirk Hekma Wierda, Utrecht (NL); Marc Coenen, Baarlo (NL); Jeroen De Jonge, Almere (NL); Fredericus J.A. Korsten, Schijndel (NL)

Correspondence Address: WEINGARTEN, SCHURGIN, GAGNEBIN & LEBOVICI LLP, TEN POST OFFICE SQUARE, BOSTON, MA, 02109, US

(21) Appl. No.: 11/807,769

(22) Filed: May 30, 2007

(51) Int. Cl. H01L 21/02

(52) U.S. Cl. 52/173.1; 52/741.1

(57) ABSTRACT

A system and a method for installing a semiconductor manufacturing apparatus comprising several modules, each of which is provided with a number of module supporting feet at a bottom side. The system and the method comprise a supporting point reduction frame, having an upper side and a bottom side, said frame at the upper side being provided with a number of first supporting points, such that each foot of a module of said semiconductor manufacturing apparatus corresponds with a first supporting point, said supporting point reduction frame at the bottom side being provided with a number of second supporting points, whereby the total number of module supporting feet exceeds said number of second supporting points, and the stiffness of said supporting point reduction frame being such that, during transportation, deviations in the relative positions of the modules mounted on said supporting point reduction frame remain within specified transportation limits.

### FIELD

The present invention relates to a system and a method for installing a semiconductor manufacturing apparatus comprising several modules.

### BACKGROUND

Bringing about the proper functioning of an advanced modular semiconductor manufacturing apparatus, such as the ASM A412 vertical furnace system of applicant, at a customer site requires the execution of a series of steps. This series commonly comprises the consecutive steps of (i) mounting the separate modules on a test pedestal at an assembly site, (ii) adjusting the mounted modules relative to each other such that they can operate as a whole, (iii) testing the proper functioning of the semiconductor manufacturing apparatus, (iv) dismounting the separate modules from the test pedestal, (v) transporting the separate modules from the assembly site to the customer site, at which site the steps (i), (ii) and (iii) will have to be performed again, this time with respect to a customer pedestal. To reduce the amount of work to be carried out at the customer site, and with it the number of manufacturer employees necessary at said site, the proper functioning of the semiconductor manufacturing apparatus to be installed is generally realized beforehand at a manufacturer's assembly and test site (steps (i), (ii) and (iii)). Here skilled personnel have the tools and spare parts on hand to perform the necessary steps and to readily deal with any problem that may arise. Nevertheless, these steps need to be duplicated at the customer site.

The known method for installing a semiconductor manufacturing apparatus thus requires a number of laborious steps, rendering the procedure costly in terms of both time and expenses. Therefore, there is a need for a system and a method that provide for a means for making the aforementioned procedure more efficient, thereby cutting expenses and shortening the order-to-delivery cycle.

### SUMMARY

To this end, the present invention provides a system, comprising
a semiconductor manufacturing apparatus comprising several modules, each of which is provided with a number of module supporting feet at a bottom side, and
a supporting point reduction frame, having an upper side and a bottom side, said supporting point reduction frame at the upper side being provided with a number of first supporting points, such that each foot of a module of said semiconductor manufacturing apparatus corresponds with a first supporting point, said supporting point reduction frame at the bottom side being provided with a number of second supporting points, whereby the total number of module supporting feet exceeds said number of second supporting points, and the stiffness of said supporting point reduction frame being such that, during transportation, deviations in the relative positions of the modules mounted on said supporting point reduction frame remain within specified transportation limits.
   The invention also provides a method for installing a semiconductor manufacturing apparatus, comprising at least two modules, comprising the steps of
providing a semiconductor manufacturing apparatus comprising at least two modules, each of which is provided with a number of module supporting feet at a bottom side,
providing a supporting point reduction frame, having an upper side and a bottom side, said supporting point reduction frame at the upper side being provided with a number of first supporting points, such that each foot of a module of said semiconductor manufacturing apparatus corresponds with a first supporting point, said supporting point reduction frame at the bottom side being provided with a number of second supporting points, whereby the total number of module supporting feet exceeds said number of second supporting points, and the stiffness of said supporting point reduction frame being such that, during transportation, deviations in the relative positions of the modules mounted on said supporting point reduction frame remain within specified transportation limits.
mounting the modules on the supporting point reduction frame at an assembly site,
adjusting the mounted modules relative to each other, such that they can operate as a whole,
transporting the supporting point reduction frame, along with the mounted and mutually adjusted modules, from the assembly site to a customer site, whereby deviations in the relative positions of the modules mounted on the supporting point reduction frame remain within specified transportation limits,
mounting the supporting point reduction frame, along with the mounted and mutually adjusted modules, on a receiving pedestal at the customer site, whereby deviations in the relative positions of the modules mounted on the supporting point reduction frame remain within specified operating limits.

At an assembly site the supporting point reduction frame is mounted on a test pedestal, whereby the second supporting points of the supporting point reduction frame cooperate with corresponding supports of the pedestal. Then, the modules of the semiconductor manufacturing apparatus are mounted on the supporting point reduction frame, whereby the different module supporting feet cooperate with the corresponding first supporting points of the supporting point reduction frame. Once mounted, the positions of the modules can be adjusted relative to each other by adjusting the feet thereof, e.g. the heights of the feet. For the modules to properly function as a whole, their relative positions need to be adjusted very accurately. Deviations as small as a a millimeter may cause malfunctioning of the entire system. When testing shows that the modules properly function as a whole, the supporting point reduction frame, along with the mounted and mutually adjusted modules, is dismounted from the test pedestal and transported from the assembly site to a customer site. The stiffness of the supporting point reduction frame ensures that the relative alignment of the modules is preserved during transport, at least within the transportation limits. This is not trivial as the weight of a semiconductor manufacturing system can be substantial, as an example the weight of ASM's A412 vertical furnace system in about 6000 kg. Any deformation the supporting point reduction frame may undergo during transport is substantially elastic. At the customer site, the supporting point reduction frame, along with the mounted and mutually adjusted modules, is mounted on a customer pedestal, which can be substantially identical to the test pedestal. Thus, advantageously, the installation procedure of the semiconductor manufacturing apparatus has been shortened by eliminating the need for remounting and readjusting the modules at the customer site.

A first or second supporting point can simply be a flat part of a beam member of the supporting point reduction frame. However, it is also possible that the supporting point reduction frame has specific provisions which clearly define the position of a supporting point. In fact, the supporting points of the supporting point reduction frame are defined by the feet of the modules and the supports of the pedestal cooperating with the supporting point reduction frame.

According to a further elaboration of the invention the system comprises a pedestal, whereby said pedestal comprises a number of supports for cooperation with the second supporting points, the number of supports being less than the total number of module supporting feet, and the stiffness of the supporting point reduction frame being such that, during operation, deviations in the relative positions of the modules mounted on said supporting point reduction frame remain within specified operation limits.

The pedestal provides a solid foundation for the semiconductor manufacturing apparatus, the installation of which can be expedited by installing the pedestal at the customer site before the supporting point reduction frame, along with the mounted modules, is brought in. Further, the pedestal's relatively low number of supports, generally corresponding with the relatively low number of second supporting points of the supporting point reduction frame, also contributes to a speedy installation of the semiconductor manufacturing apparatus at the customer site, without the need for the presence of a large number of manufacturer employees at the customer site.

According to a further elaboration of the invention, the specified transportation limits are between 0 mm and 2 mm.

As long as deviations in the relative positions of the modules remain within the transportation limits during transportation, no damage occurs to the semiconductor manufacturing apparatus because of the relative movement of its modules.

According to a further elaboration of the invention, the specified operation limits are between 0 mm and 2 mm.

As long as deviations in the relative positions of the modules remain within the operation limits, the proper functioning of the semiconductor manufacturing apparatus is ensured. Deviations in the positions of the modules may be caused by transportation of the mounted semiconductor manufacturing apparatus, vibrations undergone by the supporting point reduction frame resulting from both inside or outside the semiconductor manufacturing apparatus, temperature influences etcetera.

According to a further embodiment of the invention the pedestal comprises at least one height adjustment mechanism operable to adjust the vertical position of at least one of the supports of the pedestal.

Supports that can be adjusted in height facilitate levelling of the supporting point reduction frame. Further, since the supporting point reduction frame will generally be installed below floor level, the adjustable supports can be used to receive the pedestal at floor level and to subsequently lower it to the desired position.

According to a further elaboration of the invention the system comprises at least one bracket assembly for connecting a module supporting foot to the supporting point reduction frame.

Bracket assemblies can be used to fix the positions of the module feet relative to the supporting point reduction frame, thereby assuring the preservation of the relative alignment of the modules during both transport and operation.

According to a further elaboration of the invention the system comprises at least one bearing device for transporting the supporting point reduction frame, along with the modules of the semiconductor manufacturing apparatus mounted on it.

A bearing device facilitates the transportation of the entire system by actively or passively allowing it to be moved substantially parallel to the floor.

A bearing device may comprise a hoverpad, which offers the advantage of both reducing the pressure exerted by the weight of the system on the floor and cushioning the semiconductor manufacturing apparatus against irregularities of the ground surface. Alternatively, a wheel, a crawler track or the like may serve as a bearing device.

According to a further embodiment of the invention at least one bearing device is detachably connectable to the supporting point reduction frame.

A detachably connectable bearing device offers the advantage of being removable when it is no longer needed. When, for example, the supporting point reduction frame is to be lowered below floor level, the bearing devices that facilitate transportation substantially parallel to the floor are most likely superfluous.

According to a further aspect of the invention, at least one bearing device, when connected to the supporting point reduction frame, extends in the area surrounding the outer circumference of said supporting point reduction frame.

Bearing devices that extend in the area surrounding the outer circumference of the supporting point reduction frame allow it to be positioned over an opening in the floor, such as an aperture in or below which a receiving pedestal is located.

According to a further elaboration of the invention, the supporting point reduction frame is provided with at least one lift attachment for transporting the supporting point reduction frame, along with the modules of the semiconductor manufacturing apparatus mounted on it with a lifting device.

In cooperation with a lifting device a lift attachment facilitates the substantially vertical transportation of the supporting point reduction frame by supplying a point of application for lifting devices such as hoists, jacks or the like.

According to a further elaboration of the invention, the supporting point reduction frame is provided with at least one slot, the at least one slot being configured to accommodate a fork of a fork-lift truck.

A slot configured to receive a fork of a fork-lift truck allows the supporting point reduction frame to be moved by a fork-lift truck safely, without impairing the supporting point reduction frame or the modules mounted on it, keeping the relative positions of the modules within the transportation limits.

In a further elaboration of the invention, the method for installing a semiconductor manufacturing apparatus may comprise the step of levelling the supporting point reduction frame at the assembly site before mounting the modules on it.

Levelling the supporting point reduction frame before the modules are mounted on it helps to assure that the modules will be mounted in an upright position, the position in which they will commonly operate best. Generally, the levelling of the supporting point reduction frame will be encompassed by the action of mounting the supporting point reduction frame on a test pedestal.

According to a further elaboration of the method for installing a semiconductor manufacturing apparatus, the step of adjusting the mounted modules relative to each other is followed by a step of testing the cooperative operation of said modules, and returning to the step of adjusting the mounted modules if required.

With this iterative process a natural and effective method for achieving a well adjusted and well functioning ensemble of modules is obtained.

According to a further elaboration of the method for installing a semiconductor manufacturing apparatus, the step of transporting includes displacing the supporting point reduction frame, along with the mounted modules, substantially parallel to the floor using at least one hoverpad connected to the supporting point reduction frame as a bearing device to lift the supporting point reduction frame, along with the mounted modules, off the floor.

Hoverpads provide a specially suitable means for displacing the supporting point reduction frame, along with the mounted modules. Hoverpads both reduce the point pressure exerted by the weight of the system on the floor and cushion the semiconductor manufacturing apparatus against irregularities of the floor surface.

According to a further aspect of the method for installing a semiconductor manufacturing apparatus, substantially fluid impermeable plates are placed on a clean room floor surface to prevent the fluid cushion generated by the hoverpads from being depleted.

A clean room floor may be fitted with perforations, allowing an air ventilation system to abstract air through it. Since the air ventilation would counteract the working of a hoverpad, substantially fluid impermeable plates can be used to ensure the hoverpad's desired lifting effect.

These and other features and advantages of the invention will be more fully understood from the following description of an embodiment of the invention, taken together with the accompanying drawings.

### BRIEF DESCRIPTION OF THE DRAWINGS

In the drawings:

FIG. 1 is a perspective view of a supporting point reduction frame mounted on a pedestal, in accordance with one embodiment of the present invention;

FIG. 2-7 are schematic perspective views of a modular semiconductor manufacturing apparatus in the course of being installed on a pedestal;

FIG. 8 is a cut away perspective view of an installed semiconductor manufacturing apparatus;

FIG. 9 is a side view of a bracket assembly, connecting a module supporting foot to a supporting point reduction frame.

### DETAILED DESCRIPTION OF THE DRAWINGS

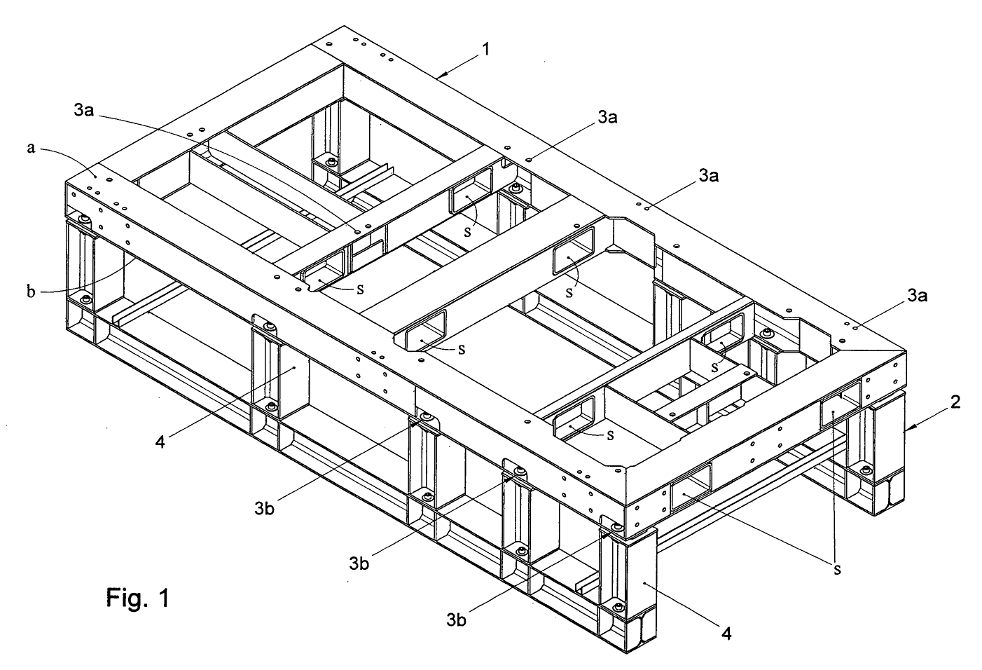

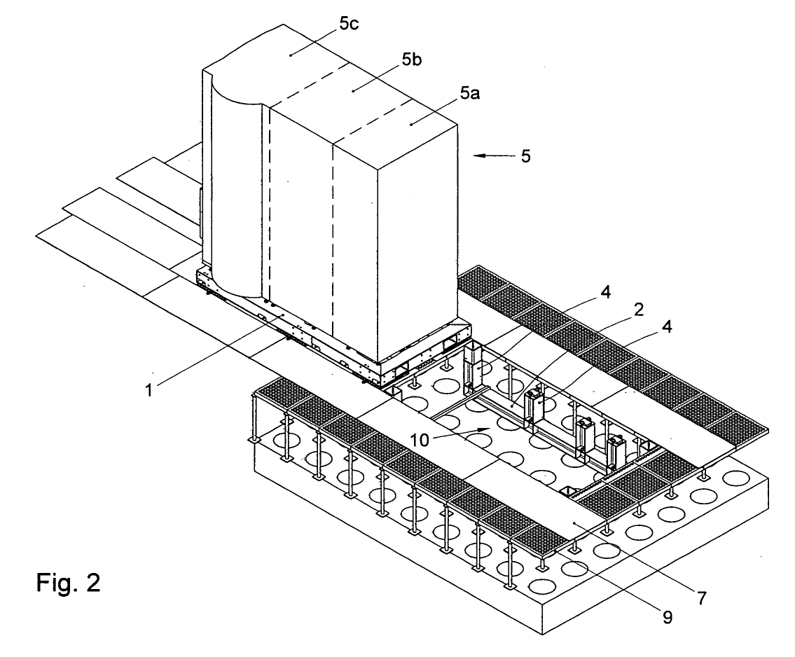

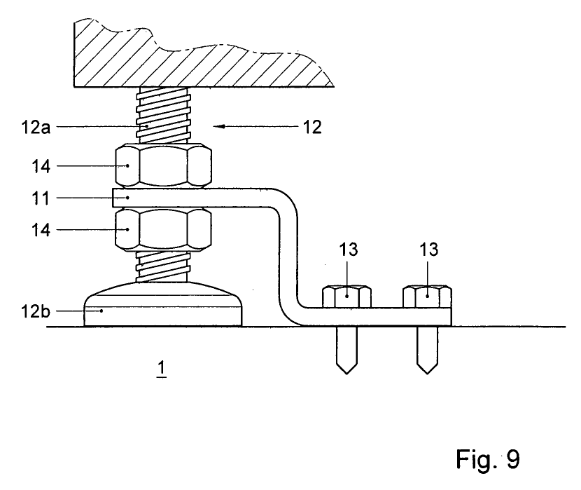

FIG. 1 illustrates a supporting point reduction frame 1 mounted on a pedestal 2. Looking to FIG. 1, the supporting point reduction frame 1 comprises an upper side a and a bottom side b. The supporting point reduction frame has a number of first supporting points 3a on which the modules 5a, 5b, 5c (see FIG. 2) of the semiconductor manufacturing apparatus 5 (see FIG. 2-8) can be mounted. The supporting point reduction frame has a number of second supporting points 3b which cooperate with the supports 4 of the pedestal 2. The supporting point reduction frame also comprises a number of slots s configured to accommodate a fork of a fork-lift truck. A configuration like the one shown in FIG. 1 may be used at a manufacturer's assembly site. There, the modules 5a, 5b, 5c (see FIG. 2) of the semiconductor manufacturing apparatus 5 (see FIG. 2-8) can be mounted on the supporting point reduction frame 1, after which the modules 5a, 5b, 5c (see FIG. 2) can be adjusted relative to each other to make them operate as a whole and testing can take place. When the semiconductor manufacturing apparatus 5 (see FIG. 2-8) operates as desired, the modules 5a, 5b, 5c (see FIG. 2) can be fixed to the supporting point reduction frame 1 using bracket assemblies like, for example, the one shown in FIG. 9. Once the relative positions of the modules 5a, 5b, 5c (see FIG. 2) are fixed, the supporting point reduction frame 1, along with the semiconductor manufacturing apparatus 5 (see FIG. 2-8) mounted on it, can be dismounted from the pedestal 2 and be transported to a customer site.

FIGS. 2-8 jointly illustrate the installation of a modular semiconductor manufacturing apparatus 5 on a pedestal 2 inside a clean room facility at a customer site. Looking to FIG. 2, the modular semiconductor manufacturing apparatus 5 is mounted on a supporting point reduction frame 1 and located next to a pedestal 2, which is located in an aperture 10, below the top floor 9. Several supports 4 of the pedestal 2 are visible.

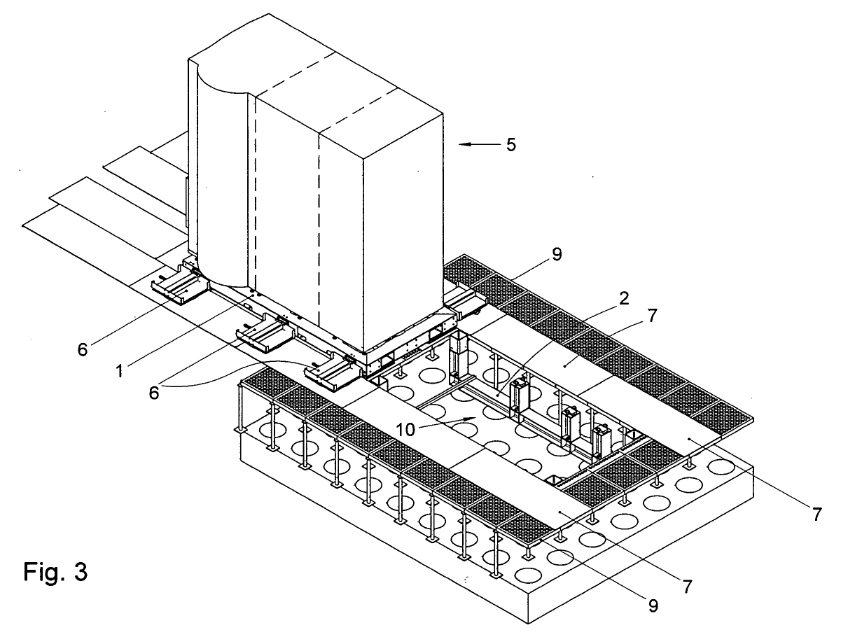

Looking to FIG. 3, a number of hoverpads 6 has been connected to the supporting point reduction frame 1. To prevent the air cushions created by the hoverpads 6 from being depleted due to air ventilation holes in the clean room floor, a number of substantially fluid impermeable plates 7 has been put on the top floor 9. It is to be noted that, alternatively, one or more wheels, crawler tracks or the like may be connected to the supporting point reduction frame 1 to facilitate its displacement substantially parallel to the floor.

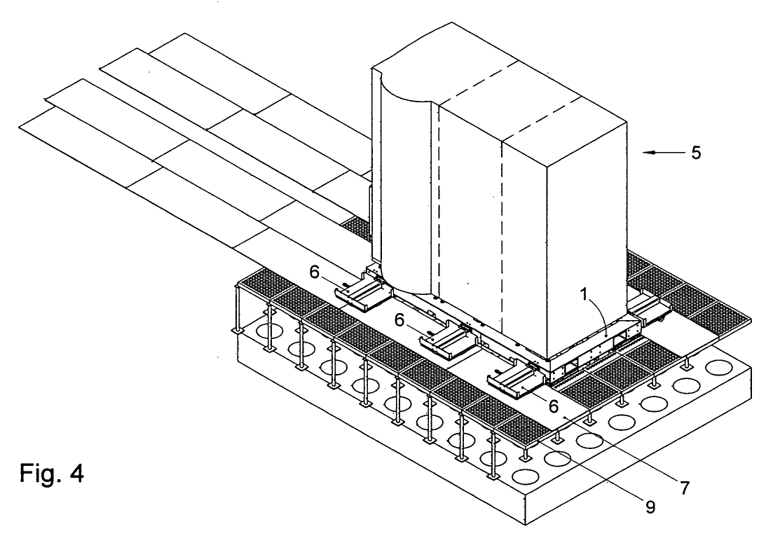

Looking to FIG. 4, the supporting point reduction frame 1, along with the mounted semiconductor manufacturing apparatus 5, has been moved over the aperture 10 (see FIG. 2-3) using the hoverpads 6.

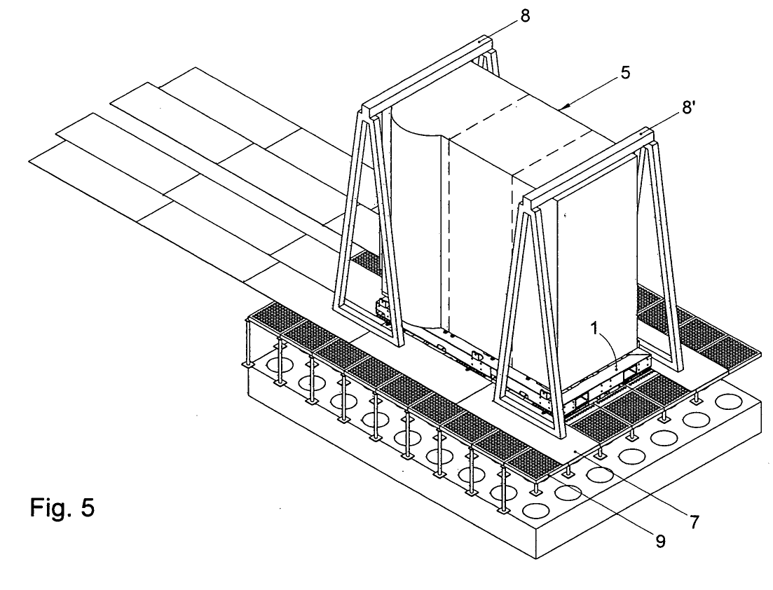

Looking to FIG. 5, two hoists 8, 8′ have been brought into place, first to suspend the supporting point reduction frame 1 so that the hoverpads 6 (see FIG. 3-4) can be removed. Subsequently the supporting point reduction frame 1, along with the semiconductor manufacturing apparatus 5, can be lowered onto the pedestal 2 (see FIG. 2-3). Preferably, the hoists are placed substantially vertically above the lift attachments provided in the support point reduction frame for attachment of the hoist cable or hoist chain. In this way, during vertically lowering of the semiconductor manufacturing apparatus 5 it can easily be aligned horizontally by exerting a slight horizontal force on the semiconductor manufacturing apparatus 5. Preferably, alignment marks, not shown, for horizontal alignment of the semiconductor manufacturing apparatus 5 relative to the floor are provided on top floor 9 and on the semiconductor manufacturing apparatus 5. The alignment marks on the semiconductor manufacturing apparatus 5 should match with the alignment marks on the floor for a proper horizontal alignment. It is understood that, alternatively, the supporting point reduction frame 1, along with the semiconductor manufacturing apparatus 5, can be lowered onto the pedestal by using other lifting means such as, for example, a jack.

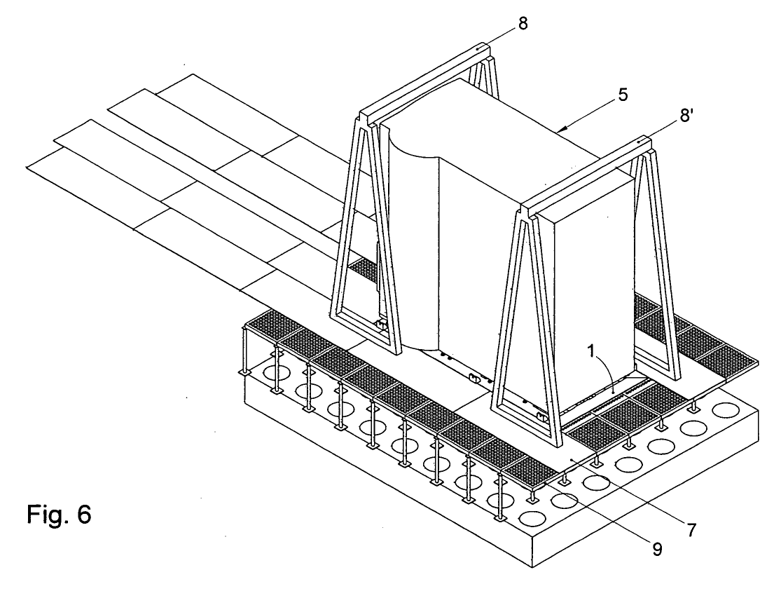

Looking to FIG. 6, the supporting point reduction frame 1, along with the semiconductor manufacturing apparatus 5, has been lowered by the hoists 8, 8′ onto the pedestal.

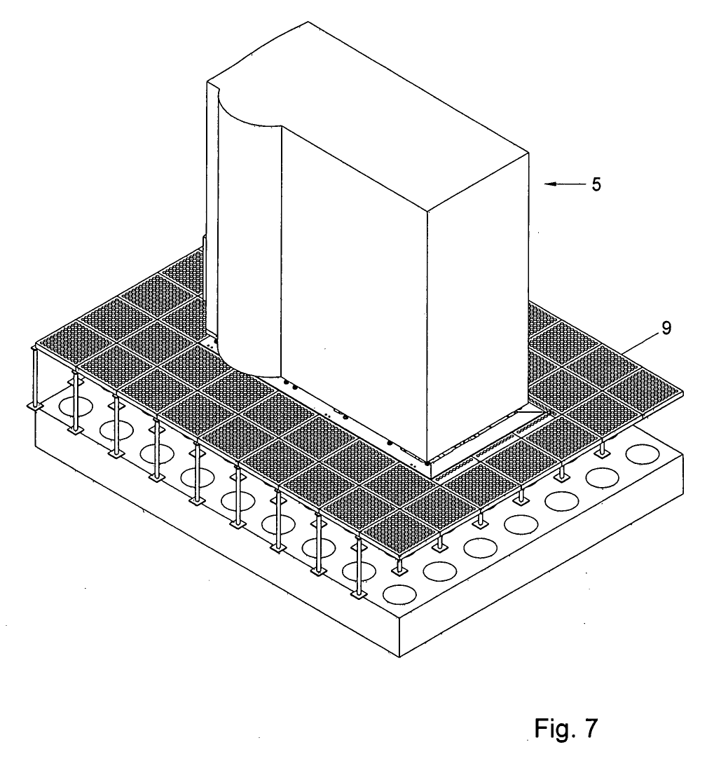

Looking to FIG. 7, the hoists 8, 8′ (see FIG. 5-6) and the substantially fluid impermeable plates 7 (see FIG. 2-6) have been removed.

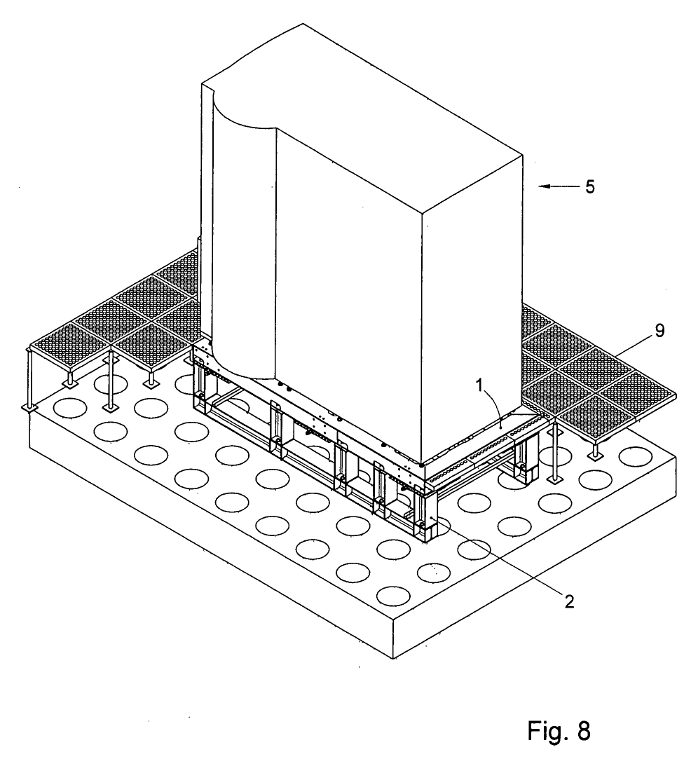

FIG. 8 shows a cut away view of an installed semiconductor manufacturing apparatus 5, mounted on a supporting point reduction frame 1, which in turn has been mounted on a pedestal 2, located below the top floor 9.

FIG. 9 illustrates a bracket assembly 11, 13, 14, connecting a module supporting foot 12 having a threaded stud 12a and a support part 12b to the supporting point reduction frame 1. The depicted bracket assembly comprises a bracket 11, two nuts 14, and two bolts 13. At one end, the bracket 11 is connected to the threaded module supporting foot 12 using the two nuts 14. At the other end, the bracket 11 is connected to the supporting point reduction frame 1 using the two bolts 13. The two bolts 13 in line eliminate both the rotational and the translational freedom of the bracket 11 relative to the supporting point reduction frame 1, thus fixing the position of the module supporting foot 12.

In an alternative embodiment the threaded module supporting foot 12, the threaded stud 12a may extend beyond the bottom side of the support part 12b of the supporting foot 12 through an accommodating hole in the supporting point reduction frame 1, and be fixed using a bracket assembly, or for example simply a nut, at and/or to a side facing away from the upper side of said frame.

While the invention has been described with reference to the accompanying drawings, and to ASM's A412 vertical furnace system, it will be understood by those skilled in the art that various changes may be made and equivalents may be substituted for elements thereof without departing from the scope of the invention. In addition, many modifications may be made to adapt to a particular situation or material to the teachings of the invention without departing from the essential scope thereof. Therefore, it is intended that the invention not be limited to any particular embodiment disclosed for carrying out this invention, but that the invention includes all embodiments falling within the scope of the appended claims.

1. A system, comprising
a semiconductor manufacturing apparatus comprising several modules, each of which is provided with a number of module supporting feet at a bottom side, and
a supporting point reduction frame, having an upper side and a bottom side, said supporting point reduction frame at the upper side being provided with a number of first supporting points, such that each foot of a module of said semiconductor manufacturing apparatus corresponds with a first supporting point, said supporting point reduction frame at the bottom side being provided with a number of second supporting points, whereby the total number of module supporting feet exceeds said number of second supporting points, and the stiffness of said supporting point reduction frame being such that, during transportation, deviations in the relative positions of the modules mounted on said supporting point reduction frame remain within specified transportation limits.

2. A system according to claim 1, further comprising a pedestal, whereby said pedestal comprises a number of supports for cooperation with the second supporting points, the number of supports being less than the total number of module supporting feet, and the stiffness of the supporting point reduction frame being such that, during operation, deviations in the relative positions of the modules mounted on said supporting point reduction frame remain within specified operation limits.

3. A system according to claim 1, whereby the specified transportation limits are between 0 and 2 mm.

4. A system according to claim 2, whereby the specified operation limits are between 0 and 2 mm.

5. A system according to claim 2, whereby said pedestal comprises at least one height adjustment mechanism operable to adjust the vertical position of at least one of the supports of the pedestal.

6. A system according to claim 1, further comprising at least one bracket assembly for connecting a module supporting foot to the supporting point reduction frame.

7. A system according to claim 1, further comprising at least one bearing device for transporting the supporting point reduction frame, along with the modules of the semiconductor manufacturing apparatus mounted on it.

8. A system according to claim 7, whereby at least one bearing device is detachably connectable to said supporting point reduction frame.

9. A system according to claim 7, whereby at least one bearing device, when connected to the supporting point reduction frame, extends in the area surrounding the outer circumference said supporting point reduction frame.

10. A system according to claim 7, whereby at least one bearing device comprises a wheel.

11. A system according to claim 7, whereby at least one bearing device comprises a hoverpad.

12. A system according to claim 7, whereby at least one bearing device comprises a crawler track.

13. A system according to claim 1, whereby said supporting point reduction frame is provided with at least one lift attachment for transporting the supporting point reduction frame, along with the modules of the semiconductor manufacturing apparatus mounted on it with a lifting device.

14. A system according to claim 1, whereby said supporting point reduction frame is provided with at least one slot, the at least one slot being configured to accommodate a fork of a fork-lift truck.

15. A method for installing a system according to claim 1, whereby said semiconductor manufacturing apparatus comprises at least two modules, comprising the steps of
providing a semiconductor manufacturing apparatus comprising at least two modules, each of which is provided with a number of module supporting feet at a bottom side,
providing a supporting point reduction frame, having an upper side and a bottom side, said supporting point reduction frame at the upper side being provided with a number of first supporting points, such that each foot of a module of said semiconductor manufacturing apparatus corresponds with a first supporting point, said supporting point reduction frame at the bottom side being provided with a number of second supporting points, whereby the total number of module supporting feet exceeds said number of second supporting points, and the stiffness of said supporting point reduction frame being such that, during transportation, deviations in the relative positions of the modules mounted on said supporting point reduction frame remain within specified transportation limits;
mounting the modules on the supporting point reduction frame at an assembly site,
adjusting the mounted modules relative to each other, such that they can operate as a whole,
transporting the supporting point reduction frame, along with the mounted and mutually adjusted modules, from the assembly site to a customer site, whereby deviations in the relative positions of the modules mounted on the supporting point reduction frame remain within specified transportation limits,
mounting the supporting point reduction frame, along with the mounted and mutually adjusted modules, on a receiving pedestal at the customer site, whereby deviations in the relative positions of the modules mounted on the supporting point reduction frame remain within specified operating limits.

16. Method according to claim 15 comprising the step of levelling the supporting point reduction frame at the assembly site before mounting the modules on it.

17. Method according to claim 15, whereby the step of adjusting the mounted modules relative to each other is followed by a step of testing the cooperative operation of said modules, and returning to the step of adjusting the mounted modules if required.

18. Method according to claim 15, whereby the step of transporting includes displacing the supporting point reduction frame, along with the mounted modules, substantially parallel to the floor using at least one hoverpad connected to the supporting point reduction frame as a bearing device to lift the supporting point reduction frame, along with the mounted modules, off the floor.

19. Method according to claim 16, whereby substantially fluid impermeable plates are placed on a clean room floor surface to prevent the fluid cushion generated by the hoverpads from being depleted.

20. A system according to claim 4, whereby said pedestal comprises:
at least one height adjustment mechanism operable to adjust the vertical position of at least one of the supports of the pedestal;
at least one bracket assembly for connecting a module supporting foot to the supporting point reduction frame;
at least one bearing device for transporting the supporting point reduction frame, along with the modules of the semiconductor manufacturing apparatus mounted on it;
at least one bearing device detachably connectable to said supporting point reduction frame;
at least one bearing device, when connected to the supporting point reduction frame, extending in the area surrounding the outer circumference said supporting point reduction frame;
at least one bearing device comprising a wheel, a hoverpad or a crawler track;
said supporting point reduction frame provided with at least one lift attachment for transporting the supporting point reduction frame, along with the modules of the semiconductor manufacturing apparatus mounted on it with a lifting device;
said supporting point reduction frame provided with at least one slot, the at least one slot being configured to accommodate a fork of a fork-lift truck.

21. A method for installing a system according to claim 20, whereby said semiconductor manufacturing apparatus comprises at least two modules, comprising the steps of
providing a semiconductor manufacturing apparatus comprising at least two modules, each of which is provided with a number of module supporting feet at a bottom side,
providing a supporting point reduction frame, having an upper side and a bottom side, said supporting point reduction frame at the upper side being provided with a number of first supporting points, such that each foot of a module of said semiconductor manufacturing apparatus corresponds with a first supporting point, said supporting point reduction frame at the bottom side being provided with a number of second supporting points, whereby the total number of module supporting feet exceeds said number of second supporting points, and the stiffness of said supporting point reduction frame being such that, during transportation, deviations in the relative positions of the modules mounted on said supporting point reduction frame remain within specified transportation limits;
mounting the modules on the supporting point reduction frame at an assembly site,
adjusting the mounted modules relative to each other, such that they can operate as a whole,
transporting the supporting point reduction frame, along with the mounted and mutually adjusted modules, from the assembly site to a customer site, whereby deviations in the relative positions of the modules mounted on the supporting point reduction frame remain within specified transportation limits,
mounting the supporting point reduction frame, along with the mounted and mutually adjusted modules, on a receiving pedestal at the customer site, whereby deviations in the relative positions of the modules mounted on the supporting point reduction frame remain within specified operating limits;
the step of levelling the supporting point reduction frame at the assembly site before mounting the modules on it;
the step of adjusting the mounted modules relative to each other followed by a step of testing the cooperative operation of said modules, and returning to the step of adjusting the mounted modules if required;
the step of transporting including displacing the supporting point reduction frame, along with the mounted modules, substantially parallel to the floor using at least one hoverpad connected to the supporting point reduction frame as a bearing device to lift the supporting point reduction frame, along with the mounted modules, off the floor.
